(19) United States
(12) Patent Application Publication
(10) Pub. No.: US 2004/0099525 A1
(43) Pub. Date: May 27, 2004

(54) Method of forming oxide thin films using negative sputter ion beam source

(75) Inventors: Namwoong Paik, Hackensack, NJ (US); Minho Sohn, Glen Rock, NJ (US); Steven Kim, Harrington Park, NJ (US)

Correspondence Address: MORGAN LEWIS & BOCKIUS LLP, 1111 PENNSYLVANIA AVENUE NW, WASHINGTON, DC, 20004, US

(73) Assignee: Plasmion Corporation

(21) Appl. No.: 10/300,783

(22) Filed: Nov. 21, 2002

(51) Int. Cl. C23C 14/32

(52) U.S. Cl. 204/192.22; 204/192.15; 204/192.23; 204/192.26; 204/192.12

(57) ABSTRACT

A method of forming an oxide thin film includes introducing a work function reducing agent onto a surface of a sputter target facing into a substrate in a process chamber, providing an oxygen gas and an inert gas into the process chamber, ionizing the oxygen gas and the inert gas, thereby generating a plurality of electrons, disintegrating a plurality of negatively charged ions from the sputter target, and forming the oxide thin film on the substrate from the negatively charged ions reacted with the ionized oxygen gas.

### BACKGROUND OF THE INVENTION

1. Field of the Invention

The present invention relates to a thin film, and more particularly, to a method of forming oxide thin films using a negative sputter ion beam source. Although the present invention is suitable for a wide scope of applications, it is particularly suitable for forming oxide thin films having desirable characteristics in high packing density, high refractive index, low stress, and low surface roughness.

2. Discussion of the Related Art

Due to its low dielectric constant, high transparency, high hardness, and low refractive index, silicon dioxide (SiO₂) thin films have been widely used for optics, electronics, and tribology, etc. Other oxide thin films, such as titanium oxide (TiO₂) and tantalum oxide (Ta₂O₅), have also been employed in the above-mentioned applications.

Several deposition methods have been attempted to achieve a good quality of oxide thin films by using molecular beam epitaxy (MBE), R.F. magnetron sputtering, plasma enhanced chemical vapor deposition (PECVD), reactive pulsed laser deposition (RPLD), and ion beam assisted deposition (IBAD).

Even with the development of those sophisticated deposition techniques, there remain several problems yet to be resolved in depositing the oxide thin film. For example, an aging effect of the oxide thin films becomes a serious problem especially in optoelectronic applications such as plasma display panel (PDP) filters or dense wavelength division multiplex (DWDM) filters. An excessive change in the thickness or refractive index causes a malfunction of the device.

In case of a DWDM filter that consists of a multilayer coating more than 100 layers, aging is the main problem affecting a stable operation of the product. To minimize the change of the refractive index and the thickness of the films after deposition, the deposited thin films should be dense. One of the most efficient ways to produce dense films is known as an ion beam related deposition technique. An energetic bombardment of the target particles on the surface can densify the thin film by the excessive surface mobility of adatoms. Also, the particles provide extra energies to the surface and eventually enhance the packing density of thin films.

### SUMMARY OF THE INVENTION

Accordingly, the present invention is directed to a method of forming oxide thin films using a negative sputter ion beam (NSIB) source that substantially obviates one or more of problems due to limitations and disadvantages of the related art.

Another object of the present invention is to provide a method of forming oxide thin films using a negative sputter ion beam source that has enhanced characteristics in packing density, refractive index, stress, and surface roughness.

Additional features and advantages of the invention will be set forth in the description which follows and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a method of forming an oxide thin film includes introducing a work function reducing agent onto a surface of a sputter target facing into a substrate in a process chamber, providing an oxygen gas and an inert gas into the process chamber, ionizing the oxygen gas and the inert gas, thereby generating a plurality of electrons, disintegrating a plurality of negatively charged ions from the sputter target, and forming the oxide thin film on the substrate from the negatively charged ions reacted with the ionized oxygen gas.

In another aspect of the present invention, a method of forming an oxide thin film using a magnetron sputter system includes pre-sputtering a substrate in a process chamber to clean a surface of the substrate, evacuating the process chamber to maintain a base pressure, introducing a work function reducing agent onto a surface of a sputter target facing into the substrate, providing an oxygen gas and an inert gas into the process chamber, maintaining a process pressure of the process chamber, ionizing the oxygen gas and the inert gas, thereby generating a plurality of electrons, confining the electrons in close proximity to the surface of the sputter target, disintegrating a plurality of negatively charged ions from the sputter target, and forming the oxide thin film on the substrate from the negatively charged ions reacted with the ionized oxygen gas.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention.

In the drawings:

FIG. 1 illustrates a schematic diagram of a process chamber for forming various oxide thin films according to the present invention;

FIG. 2 illustrates a graph showing transmittance plots of a silicon oxide (SiO₂) thin film formed by using a negative sputter ion beam source according to the present invention;

FIG. 3A is an atomic force microscope image (AFM) at a low power of the SiO₂ thin film formed on the glass substrate by using the negative sputter ion beam source according to the present invention;

FIG. 3B is an atomic force microscope image (AFM) at a medium power of the SiO₂ thin film formed on the glass substrate by using the negative sputter ion beam source according to the present invention;

FIG. 3C is an atomic force microscope image (AFM) at a high power of the SiO₂ thin film formed on the glass substrate by using the negative sputter ion beam source according to the present invention;

FIG. 4A is an atomic force microscope image (AFM) of the SiO₂ thin film formed on a glass substrate by using a conventional magnetron sputter method;

FIG. 4B is an atomic force microscope image (AFM) of the SiO₂ thin film formed on the glass substrate by using the negative sputter ion beam source according to the present invention;

FIGS. 5A to 5C are scanning electron microscopy (SEM) images of the SiO₂ thin film formed on a silicon (Si) substrate by using the negative sputter ion beam source according to the present invention;

FIG. 6 illustrates a graph showing a change in an etch rate of the SiO₂ thin film formed by using the negative sputter ion beam source with different cesium (Cs) source temperatures;

FIG. 7A illustrates a graph showing abrupt changes in refractive index of the SiO₂ thin film formed by the conventional method after a long period of time elapses;

FIG. 7B illustrates a graph showing consistency in refractive index of the SiO₂ thin film formed by the negative sputter ion beam source according to the present invention after a long period of time elapses;

FIG. 8 illustrates a graph showing a comparison between refractive indices of the SiO₂ thin film formed by the negative sputter ion beam source according to the present invention and the SiO₂ thin film formed by the conventional sputter after a long period of time elapses;

FIG. 9 illustrates a graph showing an aging effect of the SiO₂ thin film formed by the negative sputter ion beam source under different power conditions with respect to various oxygen partial pressures;

FIG. 10A illustrates a graph showing an aging effect of the SiO₂ thin film formed by the negative sputter ion beam source under different power conditions with respect to refractive index (n);

FIG. 10B illustrates a graph showing an aging effect of the SiO₂ thin film formed by the negative sputter ion beam source under different power conditions with respect to a variation in thickness;

FIGS. 11A and 11B illustrate graphs each showing a comparison of the reflectance data of the SiO₂ thin film formed by the negative sputter ion beam source between a calculated value and a measured value for a one-month period, wherein FIG. 11A represents day 1 and FIG. 11B represents day 30;

FIG. 12 illustrates a graph showing a deposition rate of the SiO₂ thin film formed by the negative sputter ion beam source as a function of an applied cathode voltage; and

FIGS. 13A and 13B illustrate graphs for transmission, refractive indices, and extinction coefficients of a titanium oxide (TiO₂) thin film formed by the negative sputter ion beam source according to the present invention.

### DETAILED DESCRIPTION OF THE ILLUSTRATED EMBODIMENTS

Reference will now be made in detail to the illustrated embodiments of the present invention, examples of which are illustrated in the accompanying drawings. Wherever possible, the same reference numbers will be used throughout the drawings to refer to the same or like parts.

In the present invention, a negative sputter ion beam (NSIB) source is used to form oxide thin films, such as silicon dioxide (SiO₂), titanium oxide (TiO₂), aluminum oxide (Al₂O₃), niobium oxide (Nb₂O₅), hafnium oxide (HfO₂), and tantalum oxide (Ta₂O₅). NSIB source utilizes negative ions formed on the cesiated target surface. The negative ion formation on the cesiated surface is disclosed in U.S. Pat. No. 5,466,941, which is hereby incorporated by reference in its entirety. Detailed characteristics of the oxide thin films formed by NSIB source, such as packing density, surface morphology, wet-etch rate, and transmittance will be discussed in the present invention.

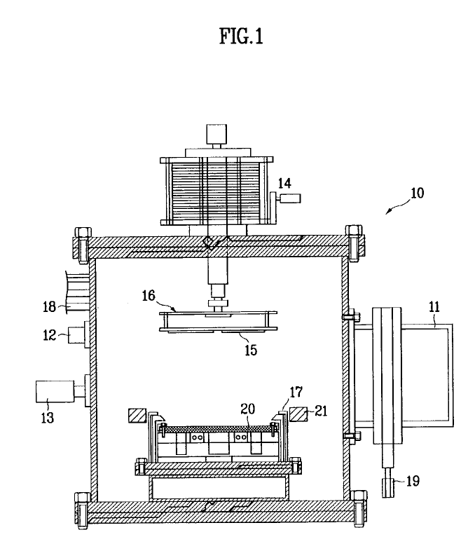

FIG. 1 illustrates a schematic diagram of a process chamber for forming various oxide thin films according to the present invention.

As shown in FIG. 1, a process chamber 10 may include a Cryo pump 11, a thermocouple gauge 12, an ion gauge 13, a sample transport system 14, a substrate 15, a substrate holder 16, a negative sputter ion beam source 17, a mass flow controller (MFC) 18 for argon and oxygen, a gate valve 19, a sputter target 20, and a cesium injector 21.

More specifically, the Cryo pump 11 (CTI-cryogenics) is attached to the process chamber 10, so that a base chamber pressure is maintained at about 10⁻⁷ to 10⁻⁶ Torr. The base chamber pressure is monitored using the thermocouple gauge 12 and the ion gauge 13. A typical operating pressure with argon plasma is in the range of 10⁻⁴ and 10⁻² Torr. An oxygen supply is independently controlled using the mass flow controller (MFC) 18.

At the bottom of the process chamber 10, an 8-inch magnetron sputter type negative ion beam source is placed to generate negative ions from the target surface. For example, an 8-inch diameter and 0.25-inch thick 99.999% p-type doped silicon target may be used as a target to form a silicon dioxide thin film on the substrate 15.

The substrate holder 16 with linear motion equipment is capable of adjusting a target-to-substrate distance. A silicon wafer or a glass substrate may be used as the substrate 15 depending upon different applications. During deposition, the gate valve 19, for example an 8-inch manual type, is located between the Cryo pump 11 and the process chamber 10 to control the process pressure. To reduce the work function of the sputter target 20, a work function reducing agent, such as cesium (Cs), rubidium (Rb), potassium (K), sodium (Na), and lithium (Li), is injected onto the surface of the sputter target 20 from cesium injector 21.

Thereafter, an oxygen gas and an inert gas, such as argon, are introduced into the process chamber 10. In order to ionize the oxygen gas and the inert gas, a voltage, such as straight DC, pulsed DC, and RF power supply, may be applied to the sputter target 20. For example, the applied voltage may be in the range of about 100 to 1000 V.

With the help of the work function reducing agent on the sputter target 20, a plurality of negatively charged ions are disintegrated from the sputter target 20 and move towards the substrate 15. The negatively charged ions are reacted with the ionized oxygen gas, thereby forming an oxide thin film on the substrate 15. Depending upon a target material, various oxide thin films, such as silicon dioxide (SiO₂), titanium oxide (TiO₂), aluminum oxide (Al₂O₃), niobium oxide (Nb₂O₅), hafnium oxide (HfO₂), and tantalum oxide (Ta₂O₅), may be obtained by using the above-described method (i.e., NSIB source).

Prior to the deposition, each substrate may be pre-sputtered with 300 eV argon ions for about 3 minutes. A DC pulsed power supply to NSIB source may be used as a power supply. The substrate may be prepared with about 40 kHz of the power supply. Although the above-described experimental conditions are used in forming a silicon dioxide thin film, these conditions may also be applicable to other oxide thin films.

The deposited oxide thin films are measured in various characteristics, such as refractive index (n), extinction coefficient (k), and thickness (t), by using a computer interfaced-spectrometer. The n, k values of the oxide thin films are measured at a wavelength of 632.8 nm. The transmittance of the oxide thin film is measured using a UV spectrometer. The transmittance data suggested in the present invention is the relative transmittance to the substrate without oxide thin films.

The n, k, and t are measured every 24 hours up to a one-month period. To minimize the experimental error, six different positions on each sample are measured and averaged for the n, k, and t. To avoid a measurement error, each measurement position is marked on the backside and measured repeatedly. The transmittance is measured on the glass substrate samples.

An atomic force microscope (AFM) is employed to obtain the surface morphology data. A 2 μm×2 μm area is scanned at a tapping mode. Surface roughness is determined by a mean roughness Rₐ.

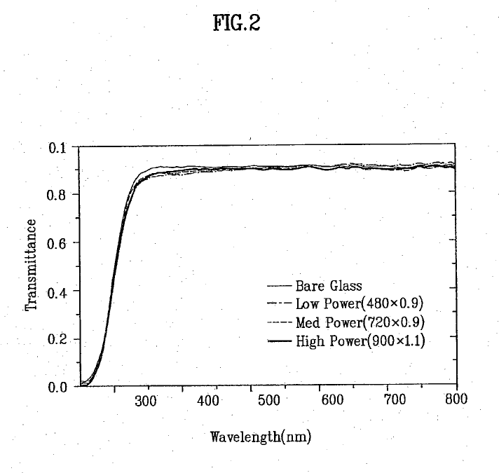

FIG. 2 illustrates a graph showing transmittance plots of a SiO₂ thin film formed by using a negative sputter ion beam source according to the present invention.

As shown in FIG. 2, the measurement shows that the SiO₂ thin film formed by using a negative sputter ion beam source has transmittance higher than about 92% transmittance in the visible wavelength region. Especially, the thin film formed at a low power shows the highest transmittance. The transmittance varies only less than 1.0% after a one-month period. Therefore, an aging effect in transmittance in the oxide thin film is not much noticeable.

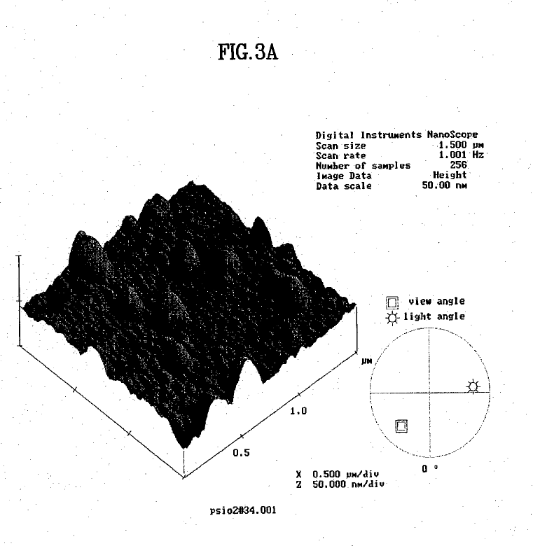

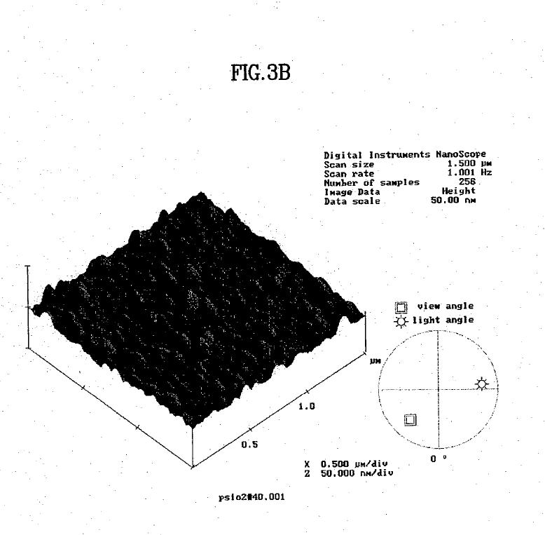

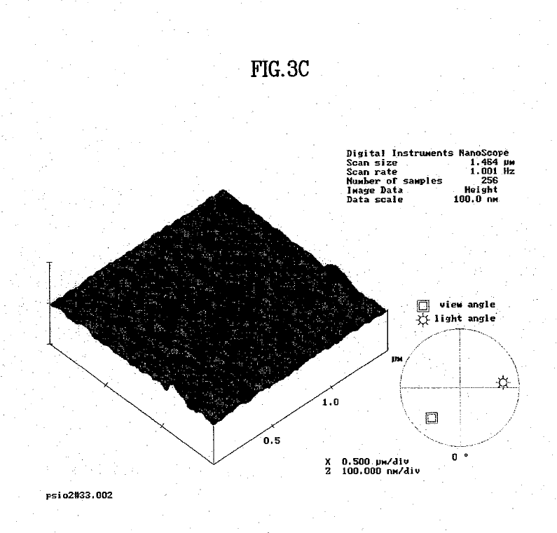

FIGS. 3A to 3C are AFM images of the SiO₂ thin films on the glass substrate under various power conditions. Each of the AFM images shows different surface morphology of the oxide thin film depending from the applied power. At a high power condition, the surface becomes smooth because a high-energy ion bombardment provides the adatoms with high surface mobility.

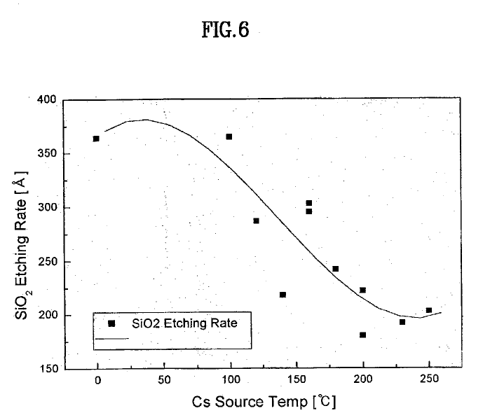

A wet-etch rate of the SiO₂ thin film is used to investigate the density of the thin film. A denser film tends to have a lower etch rate due to its high packing density. As shown in FIG. 6, a wet-etch rate depends from the flow rate of cesium. In high temperature, the cesium injector 21 produces a high cesium flow rate and gives an advantage to decrease the wet-etch rate of SiO₂ thin films. Thus, a dense oxide thin film may be deposited by using a cesium supply in the present invention.

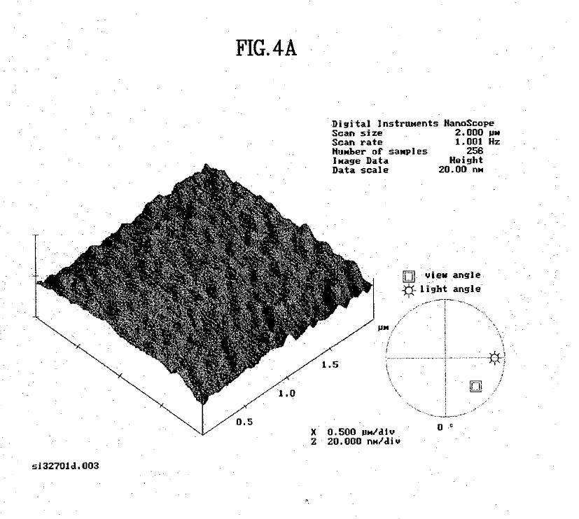

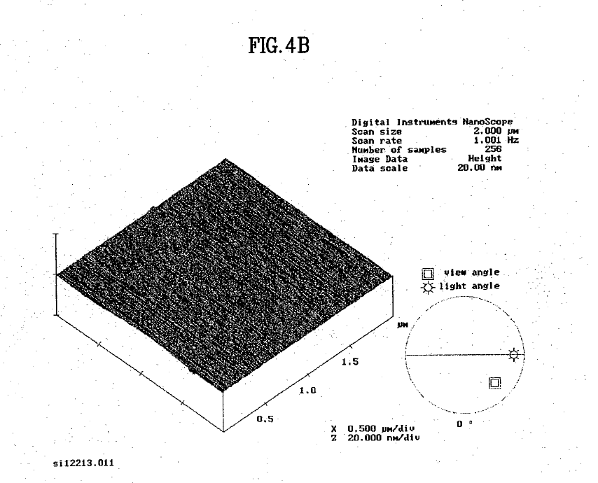

FIG. 4A is an atomic force microscope (AFM) image of a SiO₂thin film formed on a glass substrate by using a conventional magnetron sputter method, while FIG. 4B is an atomic force microscope (AFM) image of a SiO₂ thin film formed on a glass substrate by using the negative sputter ion beam source according to the present invention. As shown in FIGS. 4A and 4B, the AFM image of FIG. 4B shows a much smoother surface than that of FIG. 4A. This is due to the high-energy ion bombardment and the high-surface mobility of adatoms provided by NSIB source in the present invention.

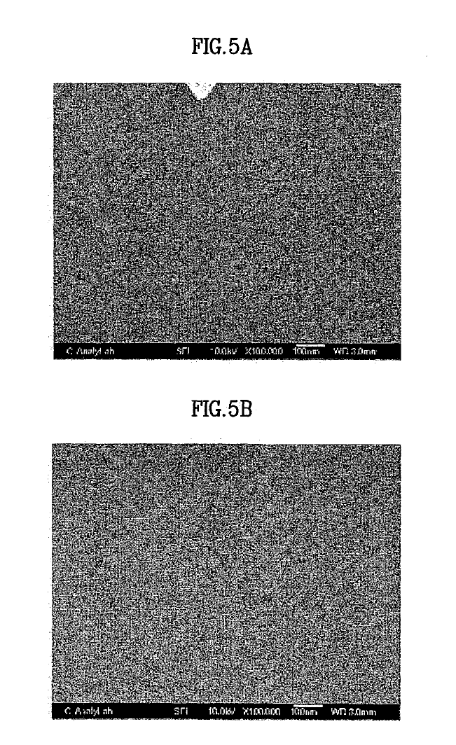

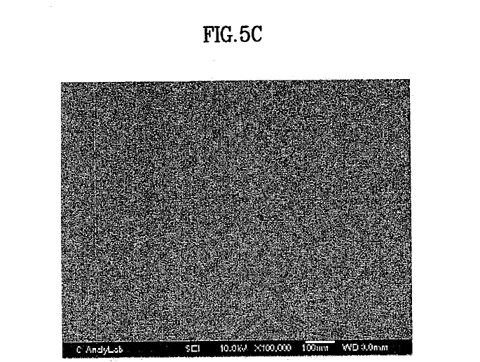

FIGS. 5A to 5C are scanning electron microscopy (SEM) images of the SiO₂ thin film formed on a silicon (Si) substrate by using the negative sputter ion beam source with different cesium injector temperatures, about 50, 150, and 250° C., respectively. At the highest temperature condition of 250° C., the film surface is not only smooth, but also highly packed because the high temperature condition is more effective for the cesium injection in producing the negative ions from the sputter target 20.

FIG. 6 illustrates a graph showing a change in an etch rate of the SiO₂ thin film formed by using the negative sputter ion beam source with different cesium (Cs) source temperatures. The wet-etch rate of the SiO₂ thin film is used to examine the density of the thin film. As shown in FIG. 6, at the low cesium temperatures, the etched amount of the SiO₂ thin film is in the range of about 350 to 400 Å for a certain period of time. When the cesium injector temperatures become higher than about 200° C., the etch rate of the thin film becomes low, indicating that the thin film has a high density.

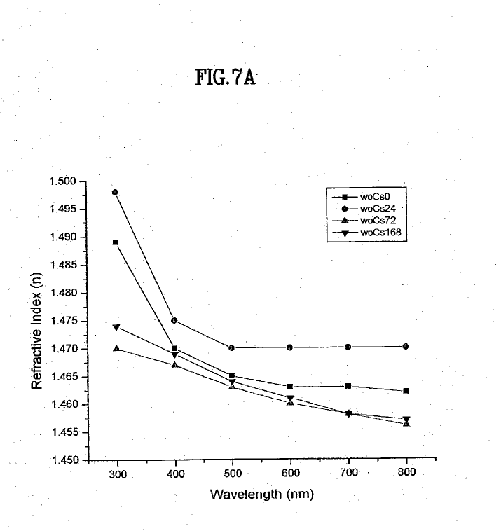

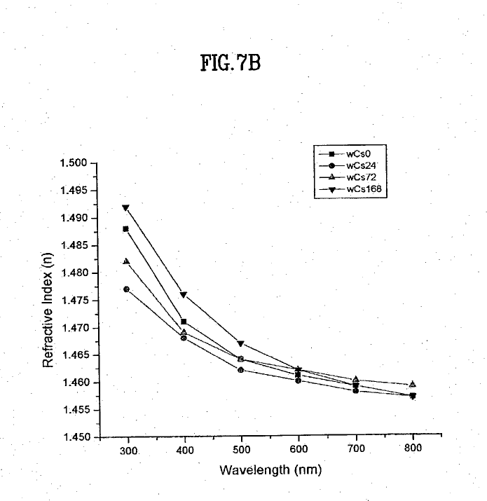

FIGS. 7A and 7B respectively illustrate graphs showing a different trend in refractive index of the SiO₂ thin films formed by the conventional method and by the negative sputter ion beam source according to the present invention after a long period of time elapses. As shown in FIGS. 7A and 7B, the oxide thin film formed by the conventional sputtering method suffers from a significant refractive index variation after a long period of time is passed. Meanwhile, the oxide thin film formed by the process in the present invention shows the consistent refractive index even after a considerable amount of time is passed.

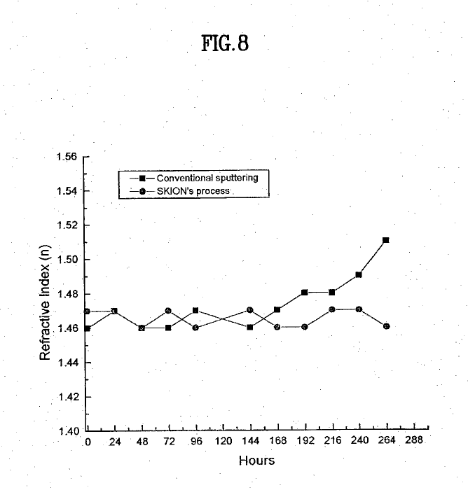

FIG. 8 illustrates a comparison between the refractive indices of the SiO₂ thin film formed by the method of the related art and that formed by the method according to the present invention. The refractive index variation is measured with respect to a wavelength of 632.8 nm.

Generally, an oxide thin film, such as SiO₂, suffers from an aging effect after the deposition is complete. In order to minimize the variation of refractive index or thickness of the thin film after the completion of the deposition, a dense film is desirable. As described above, a dense thin film is formed by using the negative ion source in the present invention.

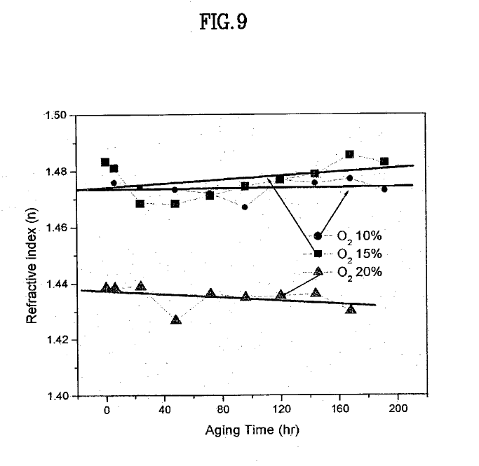

An oxygen partial pressure is one of the critical factors in the SiO₂ deposition process. FIG. 9 illustrates a graph showing an aging effect of the SiO₂ thin films under different oxygen partial pressure conditions.

FIG. 9 illustrates a graph showing an aging effect of the SiO₂ thin film formed by the negative sputter ion beam source under different power conditions with respect to various oxygen partial pressures.

As shown in FIG. 9, the oxygen partial pressure is represented as a percentage of oxygen gas with respect to an argon gas supply. As the oxygen partial pressure increases (i.e., from 10% to 15 and 20%), the refractive index of the SiO₂ thin film decreases. It is known that an ion beam deposition process induces a high oxidation state and a high packing density. The extinction coefficients of the SiO₂ films are small enough (i.e., k<3×10⁻³) to be used as an optical coating. Also, as the oxygen partial pressure increases, a decrease in a deposition rate is observed.

The power dependence is also investigated in three different power regimes: high, medium, and low power regimes. In NSIB source, the kinetic energy of particles at the substrate is the function of the cathode voltage. Since the process pressure remains the same as 10⁻⁴ to 10⁻² Torr throughout the entire deposition process, a higher power condition is considered as a higher ion beam energy condition. If the pressure is low enough to provide a collision-less transport, the most probable negative ion arrival energy may be defined as a cathode voltage.

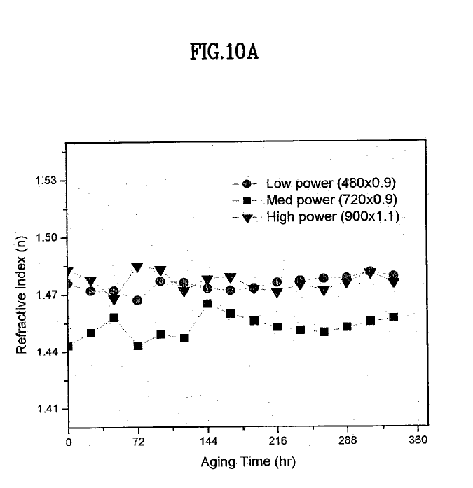

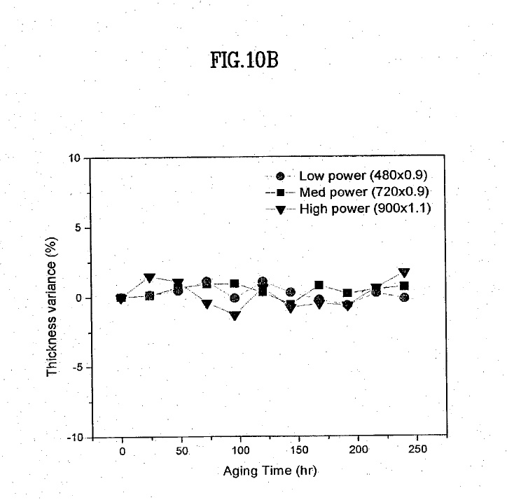

FIG. 10A illustrates a graph showing an aging effect of the SiO₂ thin film with respect to the refractive index (n). FIG. 10B illustrates a graph showing an aging effect of the SiO₂ thin film with respect to the thickness variation.

As shown in FIGS. 10A and 10B, the refractive index variation is plotted with different power regimes. In the low power regime, the refractive index variation is the smallest among the three conditions due to a low deposition rate.

It has been reported that the refractive index tends to be increased with a temperature at a certain wavelength due to enhanced surface mobility. With an energetic bombardment of particles, the same result may be obtained. Regardless of the different power setup, variation of the refractive index is more noticeable at the first 5 days than 5 days after the deposition. Variation in thickness shows the same trend.

In FIGS. 10A and 10B, both plots show a fluctuation between maximum and minimum points throughout the period. The amplitude of the fluctuation is decreased with time. In the overall variation of the refractive index, the low power condition is more stable than the other conditions. In case of the thickness variation, the high power condition is more stable than the other conditions. As shown in the data, the aging effect is related to the deposition rate of the oxide thin films.

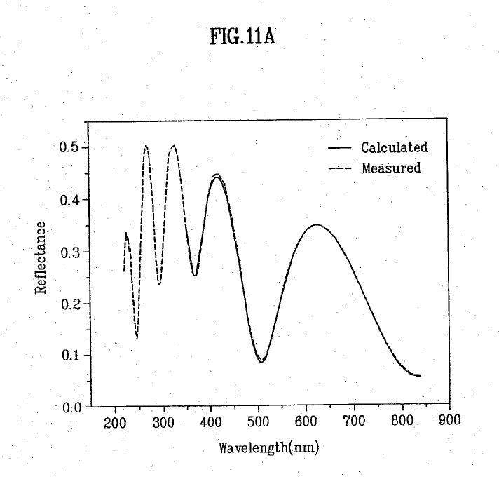

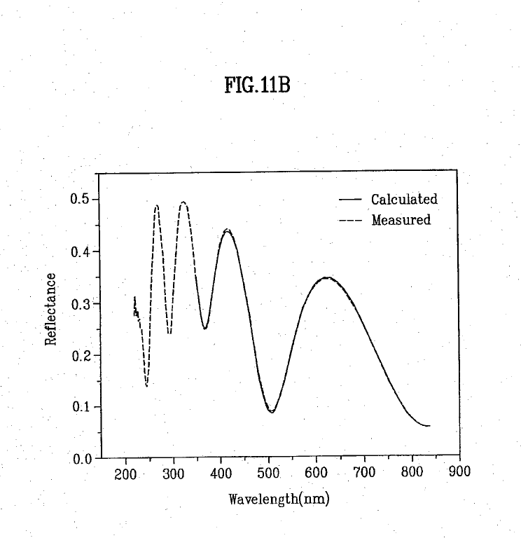

FIGS. 11A and 11B illustrate graphs each showing a comparison of the reflectance data of the SiO₂ thin film formed by NSIB source of the present invention between the calculated value and the measured value for a one-month period, wherein FIG. 11A represents day 1 and FIG. 11B represents day 30. As shown in the graphs, there is not much variation between the data of day 1 and day 30. Also, the measured data is almost the same as the calculated data.

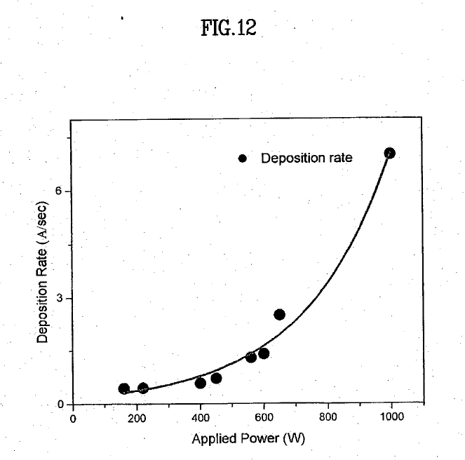

FIG. 12 illustrates a graph showing a deposition rate of the SiO₂ thin film as a function of the applied cathode voltage. The deposition rate at about 1 Kw is approximately 7 Å/sec.

The trend of the above-data may be explained as follows. Porosity, which is directly connected to the density of the oxide thin films, may be estimated through the pattern of the reflectance plots. The porosity of the thin films from the reflectance data may be examined with different wavelength regimes.

As shown in the above drawings, the good agreement between the calculated values and the measured values is indicative of a highly dense SiO₂ thin film. Meanwhile, a poor agreement between the two values indicates a highly porous film. FIGS. 11A and 11B represent porosity data of the SiO₂ thin films after an elapse of one month. The data suggest that the thin film used in this measurement remains in a dense state after the one-month period.

The deposition rate may be used for another explanation. The negative ion source employed in the present invention is based on the surface ionization by a Cs-layer on the target surface. Therefore, in high-deposition rate conditions for the industrial level, a Cs vapor flow rate plays an important role.

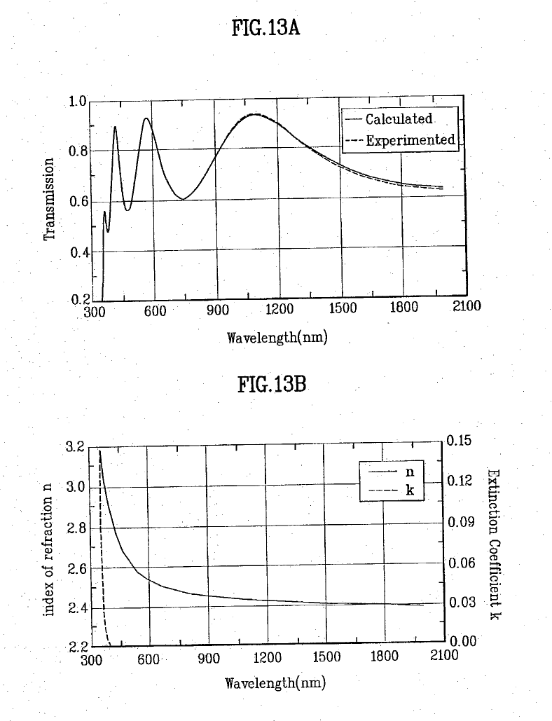

FIGS. 13A and 13B illustrate graphs for transmission, refractive indices, and extinction coefficients of a titanium oxide (TiO₂) thin film formed by the negative sputter ion beam source according to the present invention.

A titanium oxide thin film having high refractive index is desirable in most applications. In general, the refractive index is increased with temperature at a given wavelength due to enhanced surface mobility. An energetic bombardment of particles achieved by using negative sputter ion beam in the present invention may result in the same surface mobility. As shown in FIGS. 13A and 13B, a titanium oxide thin film has a high refractive index (i.e., n>2.6) and a low absorption coefficient (i.e., k<0.0005), which are never obtained by using other methods.

As described above, oxide thin films deposited by using NSIB source have desired characteristics, such as low surface roughness, low wet-etch rate, and minimal refractive index variation after the long period of time. The oxide thin film characteristics are dependent on the ion beam energy and the oxygen partial pressure. However, the variation of the refractive index and the thickness of the oxide thin films are relatively consistent. The change of the refractive index throughout the one-month period is less than 2% in most cases regardless of the refractive index value. In the conventional processes, the variation is higher than 5% after 5 days of the deposition. The aging effect is more severe in the higher deposition rate thin films.

In the present invention, characteristics of the oxide thin films are also investigated with different deposition conditions. The overall result demonstrates that desirable oxide thin films are deposited by controlling the Cs flow rate even in the higher deposition rate conditions. Also, the characteristic of the oxide thin film is varied with changing the negative ion energy. This may be an advantage in some applications such as a solar cell, in which the rougher surface is more desirable than the smoother surface.

It will be apparent to those skilled in the art that various modifications and variations can be made in the method of forming oxide thin films using a negative sputter ion beam source of the present invention without departing from the spirit or scope of the inventions. Thus, it is intended that the present invention covers the modifications and variations of this invention provided they come within the scope of the appended claims and their equivalents.

What is claimed is:

1. A method of forming an oxide thin film, comprising:
introducing a work function reducing agent onto a surface of a sputter target facing into a substrate in a process chamber;
providing an oxygen gas and an inert gas into the process chamber;
ionizing the oxygen gas and the inert gas, thereby generating a plurality of electrons;
disintegrating a plurality of negatively charged ions from the sputter target; and
forming the oxide thin film on the substrate from the negatively charged ions reacted with the ionized oxygen gas.

2. The method according to claim 1, wherein the oxide thin film includes one of silicon dioxide (SiO₂), titanium oxide (TiO₂), aluminum oxide (Al₂O₃), niobium oxide (Nb₂O₅), hafnium oxide (HfO₂), and tantalum oxide (Ta₂O₅)

3. The method according to claim 2, wherein the titanium oxide has a refractive index higher than about 2.60.

4. The method according to claim 2, wherein the titanium oxide has a low absorption coefficient less than about 0.0005.

5. The method according to claim 1, wherein the work function reducing agent includes one of cesium, rubidium, potassium, sodium, and lithium.

6. The method according to claim 1, wherein the sputter target is applied with a voltage of one of straight DC, pulsed DC, and RF power supply.

7. The method according to claim 6, wherein the applied voltage to the sputter target is in the range of about 100 to 1000 volt.

8. The method according to claim 1, wherein the substrate is either grounded or biased with respect to the sputter target.

9. The method according to claim 1, wherein the substrate is maintained at a temperature in the range of about 25 to 100° C.

10. The method according to claim 1, wherein the process chamber has a process pressure in the range of about 10⁻⁴ to 10⁻² Torr.

11. The method according to claim 1, further comprising confining the electrons in close proximity to the surface of the sputter target prior to disintegrating a plurality of negatively charged ions.

12. A method of forming an oxide thin film using a magnetron sputter system, comprising:
pre-sputtering a substrate in a process chamber to clean a surface of the substrate;
evacuating the process chamber to maintain a base pressure;
introducing a work function reducing agent onto a surface of a sputter target facing into the substrate;
providing an oxygen gas and an inert gas into the process chamber;
maintaining a process pressure of the process chamber;
ionizing the oxygen gas and the inert gas, thereby generating a plurality of electrons;
confining the electrons in close proximity to the surface of the sputter target;
disintegrating a plurality of negatively charged ions from the sputter target; and
forming the oxide thin film on the substrate from the negatively charged ions reacted with the ionized oxygen gas.

13. The method according to claim 12, wherein the oxide thin film includes one of silicon dioxide (SiO₂), titanium oxide (TiO₂), aluminum oxide (Al₂O₃), niobium oxide (Nb₂O₅), hafnium oxide (HfO₂), and tantalum oxide (Ta₂O₅).

14. The method according to claim 13, wherein the titanium oxide has a refractive index higher than about 2.60.

15. The method according to claim 13, wherein the titanium oxide has a low absorption coefficient less than about 0.0005.

16. The method according to claim 12, wherein the work function reducing agent includes one of cesium, rubidium, potassium, sodium, and lithium.

17. The method according to claim 12, wherein the sputter target is applied with a voltage of one of straight DC, pulsed DC, and RF power supply.

18. The method according to claim 17, wherein the applied voltage to the sputter target is in the range of about 100 to 1000 volt.

19. The method according to claim 12, wherein the substrate is either grounded or biased with respect to the sputter target.

20. The method according to claim 12, wherein the substrate is maintained at a temperature in the range of about 25

21. The method according to claim 12, wherein the process pressure is in the range of about 10⁻⁴ to 10⁻² Torr.

22. The method according to claim 12, wherein the base pressure is in the range of about 10⁻⁷ to 10⁻⁶ Torr.
